(19) United States
(12) Patent Application Publication
(10) Pub. No.: US 2018/0177086 A1
(43) Pub. Date: Jun. 21, 2018

(54) ASSEMBLY AND METHOD FOR HANDLING COMPONENTS

(71) Applicant: ISMECA SEMICONDUCTOR HOLDING SA, La Chaux-de-Fonds (CH)

(72) Inventors: Guy RAMEL, Orges (CH); Pierrick ABRIAL, Neuchâtel (CH); Raphael EIGELDINGER, Colombier (CH)

(73) Assignee: ISMECA SEMICONDUCTOR HOLDING SA, La Chaux-de-Fonds (CH)

(21) Appl. No.: 15/569,362

(22) PCT Filed: Jul. 31, 2015
(86) PCT No.: PCT/EP2015/067671

§ 371 Date: Oct. 25, 2017

(51) Int. Cl. H05K 13/04; H05K 13/08

(52) U.S. Cl. CPC H05K 13/0413; H05K 13/08

(57) ABSTRACT

According to the present invention there is provided method of handling components, the method comprising the steps of: (a) aligning a component into a predefined orientation using an alignment means; (b) placing the component onto a predefined position on a boat which is located in a loading area; (c) capturing a first image of the component after it has been placed on the boat with a first camera; (d) using the first image to identify if the component is in a predefined orientation on the boat; (e) if the component is not in said predefined orientation on the boat, then picking the component from the boat and aligning the component again using said alignment means. There is further provided a corresponding assembly for handling components.

### FIELD OF THE INVENTION

The present invention concerns an assembly and method for handling components, and in particular an assembly and method which involves aligning a component into a predefined orientation using an alignment means, placing the aligned component onto a boat, capturing an image of a component after it has been placed on a boat and identifying from that image if the component is in a predefined orientation on the boat, and if it is determined that the component is not in the predefined orientation subsequently picking the component and passing it to the alignment means where is realigned again.

### DESCRIPTION OF RELATED ART

Components are typically transported in a processing assembly using carriers such as boats. The components to be transported are loaded on the surface of the boat at a loading area, and the boat then transports the loaded components. It is important that the components are loaded to the correct position on the boat; for example, so as to allow efficient use of the limited space available on the boat and/or so as to ensure that the components are in a suitable position for testing i.e. in a position where they can contacted by contacts of a test station. To ensure that the components are loaded to the correct position on the boat each component is usually aligned into a predefined orientation/position prior being placed on the boat.

However even if the component is aligned into a predefined orientation/position prior being placed on the boat, the component can become displaced from its aligned position as the component is placed on the boat or during the placing of subsequent components on the boat. Consequently the component may be incorrectly positioned on the boat after it is placed.

It is an aim of the present invention to mitigate or obviate at least some of the above-mentioned disadvantages.

### BRIEF SUMMARY OF THE INVENTION

According to the invention, there is provided method of handling components, the method comprising the steps of:

(a) aligning a component into a predefined orientation using an alignment means;

(b) placing the component onto a predefined position on a boat which is located in a loading area;

(c) capturing a first image of the component after it has been placed on the boat with a first camera;

(d) using the first image to identify if the component is in a predefined orientation on the boat;

(e) if the component is not in said predefined orientation on the boat, then picking the component from the boat and aligning the component again using said alignment means.

It should be understood that the components are preferably electronic components such as LED's.

The method may comprise the step of, moving a component from a station where step (a) is performed to a station where step (b) by rotating, in a first single direction, a rotatable turret, which has a handling head which holds the component; and wherein the step of picking the component from the boat if the component is not in a predefined orientation on the boat may be performed by a component handling head on the rotatable turret; and wherein the method may further comprise the step of rotating the turret in said first single direction after the component has been picked to bring the picked component to the station where step (a) is performed again.

The method may comprises the step of moving the picked component around a full rotation of the turret after it has been picked before repeating steps (b)-(e) at least. The method may comprises the step of moving the picked component around a full rotation of the turret after it has been picked before repeating steps (a)-(e).

The method may comprise the step of moving a component between a series of processing stations by rotating, in a first single direction, a rotatable turret, which has a handling head which holds the component, before performing steps (b)-(e) at least, and wherein the method further comprises the step of passing a picked component through the series of processing stations for a second time after it has been picked. Preferably said alignment means which performs step (a) defines at least one of said processing stations.

The method may comprise the step of moving a component between a series of processing stations by rotating, in the first single direction, a rotatable turret, which has a handling head which holds the component, before performing steps (a)-(e) at least, and wherein the method further comprises the step of passing a picked component through the series of processing stations for a second time after it has been picked. Preferably, in this case, said alignment means which performs step (a) does not define one of said processing stations.

The method may further comprise, repeating steps (b)-(e) on the component which was picked and aligned again.

The step of aligning an component into a predefined orientation using an alignment means may comprise, using a camera to capture an image of the component held on the component handling head and using that image to identify the orientation of the component held on the component handling head; determining based on the orientation of the component shown in the image how the orientation of the component should be adjusted to move the component into the predefined orientation; transferring the component from the component handling head to an alignment arm of an alignment means; adjusting, using the alignment arm, the orientation of the component by the determined amount to move the component into the predefined orientation; picking the component from the alignment arm using the component handling head. In another embodiment the step of aligning an component into a predefined orientation using an alignment means may comprise, holding the component using a handling head on turret, using a camera to identify the orientation of the component which is being held by the handling head, moving the component while it is held by the handling head into its predefined orientation.

The method may comprise the steps of, repeating steps (a)-(e) until a predefined plurality of components are on the boat; capturing a second image of the boat and plurality of components, after the predefined plurality of components have been placed on the boat and before moving the boat from the loading area.

The method may comprise the step of, using the second image to determine if the plurality of components are each located at predefined positions on the boat.

The first image may be used to ensure that a component is placed at the correct orientation on the surface boat during the placing of that component on the boat; this may include ensuring that the component is in a predefined position with respect to a predefined reference frame. The second image may be used to check that all the placed components have been placed in the correct positions on the boat; e.g. that all the components have been placed in a pattern on the surface of the boat corresponding to a pattern selected by a user.

The step of using the second image to determine if the plurality of components are each located at predefined positions on the boat may comprise comparing the second image to a predefined reference image, a predefined reference map, or a predefined reference pattern, which indicate the positions on the boat which the plurality of components should occupy. If the second image does not match the reference image, or if the locations which the components occupy do not correspond to the locations illustrated on predefined reference map, of if the pattern formed by the plurality of components on the boat does not match the predefined reference pattern, then it can be determined that one or more components is/are not located at its/their predefined positions on the boat.

The method may comprise, if it is determined, using the second image, that one or more components are not located its/their predefined positions on the boat, then, identifying the locations of the one or more components which are not located in their respective predefined positions and consecutively picking said one or more components only from the boat using respective component handling heads on the turret, so as to remove said one or more components; rotating the turret in the first single direction so that the picked components are consecutively brought to a station where step (a) is performed again. In another embodiment the method may comprise, if it is determined, using the second image, that one or more components are not located its/their predefined positions on the boat, then, consecutively picking all components from the boat using respective component handling heads on the turret, so as to remove all components which were placed on the boat; rotating the turret in the first single direction so that the picked components are consecutively brought to a station where step (a) is performed again.

Importantly any one or more of the steps described above which may be performed when an individual component is picked based on the first image, may also be carried out for each of the plurality of components which are picked based on the second image.

For example, each of the plurality of components may have been passed through a series of processing stations prior to performing steps (a)-(e). The method may further comprises the step of passing each of the picked components through the series of processing stations for a second time after they have been picked, as described above. As a further example the method may comprise the step of repeating steps (b)-(e) for each of the plurality of components which are picked. The method may comprise the step of moving each of the picked component around a full rotation of the turret after it has been picked before repeating steps (b)-(e) at least. The method may comprise the step of moving each of the picked component around a full rotation of the turret after it has been picked before repeating steps (a)-(e).

A method may further comprise the steps of, transporting the boat to a testing station where the components on the boat are to be tested; capturing a third image of the boat and said components which have been placed on the boat; using the third image to determine if a component has become displaced during the transport of the boat to the testing station.

The step of using the third image to determine if a component has become displaced during the transport of the boat may comprise, comparing the third image and the second image; identifying, based on the comparison of the third and second images, if a component has become displaced during the transport of the boat to the testing station.

The steps of transporting, capturing, comparing and identifying may carried out on the condition that it has been determined, using the second image, that all components are located in their respective predefined positions on the boat.

In a variation of the present invention the step of using the third image to determine if a component has become displaced during the transport of the boat may comprise the step of comparing the third image to a predefined reference map, a predefined reference pattern or predefined reference image which indicate the positions on the boat which the plurality of components should occupy. Advantageously this variation illuminates the need for capturing the second image prior to transport.

The method may further comprise the step of aligning the boat into a predefined position at the testing station prior to capturing the third image.

The method may further comprise the step of aligning the boat into a predefined position at the testing station prior to performing testing of the components on the boat.

A guiding means may be used to facilitate moving the boat into a predefined position at the testing station. For example the boat may be aligned into a predefined position as the testing station by arranging the boat so that projections (e.g. pogo pins) at the testing station are received into recesses (e.g. fiducials) on the boat, or vice-versa. The guiding means may take other forms such as markings etc. A camera may be used to facilitate moving of the boat into its predefined position.

The method may further comprise the steps of, if it is identified that no component has become displaced during transport of the boat to the testing station, then, performing testing of the components on the boat; if it is identified that one or more components have become displaced during transport of the boat to the testing station, then, returning the boat to a loading area without testing any of the components on the boat, and, either,

identifying the positions of the displaced components, and consecutively picking the displaced components only from the boat using respective component handling heads on a turret, so as to remove the displaced components only from the boat, and, rotating the turret in a first single direction so that each of the picked components are consecutively brought to a station where step (a) is performed again, or,

consecutively picking all components from the boat using respective component handling heads on a turret, so as to remove all components from the boat, and, rotating the turret in a first single direction so that each of the picked components are consecutively brought to a station where step (a) is performed again.

In the present application is should be understood that picking all components from the boat means picking all components so that there are no components remaining on the boat and the boat is thus empty.

The step of performing testing of the components on the boat comprises moving an electrical contact of the testing station into electrical contact with electrical contacts of a component on the boat. This step may be performed for each component on the boat so that each component can be tested consecutively.

The method may further comprise the steps of, transporting the boat to a testing station where the components on the boat are tested; after testing the components on the boat at the testing station: transporting the boat from a testing station to an unloading station where components on the boat can be unloaded; capturing a fourth image of the boat and said plurality of loaded components at the unloading station; using the fourth image to determine if a component has become displaced during the transport of the boat to the unloading station.

The step of using the fourth image to determine if a component has become displaced during the transport of the boat to the unloading station may comprise, comparing the fourth image to the second image; and identifying, based on the comparison of the second and fourth images, if a component has become displaced during the transport of the boat.

The method may further comprise the step of, if a component has become displaced during the transport of the boat to the unloading station, using the first camera to identify the location of displaced component for picking.

Preferably the first camera has a field of view which is smaller than the field of view of camera(s) which capture the second and/or third and/or fourth images.

The method may further comprise the step of applying a vacuum force to components on the boat during loading and/or unloading and/or transport of the boat, which holds the components on the boat.

The step of aligning an component into a predefined orientation using an alignment means may comprise, using a camera to capture an image of the component held on the component handling head and using that image to identify the orientation of the component held on the component handling head; determining based on the orientation of the component shown in the image how the orientation of the component should be adjusted to move the component into the predefined orientation; transferring the component from the component handling head to an alignment arm of an alignment means; adjusting, using the alignment arm, the orientation of the component by the determined amount to move the component into the predefined orientation; picking the component from the alignment arm using the component handling head. In another embodiment the step of aligning an component into a predefined position using an alignment means may comprise, holding the component on a handling head of a rotatable turret; using a camera to identify the orientation of the component held on the handling head; using a moving means to move the component into the predefined orientation on the handling head.

The predefined orientation on the component handling head into which the component is moved is so that when the handling head places the component on the boat the component will occupy a predefined orientation on the surface of the boat.

Preferably the predefined orientation on the handling head into which the component is moved is an orientation in which electrical contacts of the component will occupy a predefined orientation on the boat when the component is placed on the boat by the handling head. The predefined orientation on the boat which the electrical contacts of the component will occupy, is preferably an orientation which corresponds to the orientation of electrical contacts of the testing station; this allows the electrical contacts to electrically contact the components on the boat when the boat is moved to the testing station.

According to a further aspect of the present invention there is provided a component handling assembly suitable for carrying a method according to any one of the above-mentioned methods, the assembly comprising:

(a) an alignment means operable to align an component into a predefined orientation;

(b) a turret comprising one or more component handling heads each of which can place an component on a boat which is located in a loading area;

(c) a first camera arranged for capturing a first image of an component after it has been placed on the boat;

(d) a processor configured such that it can use the first image to identify if the component in a predefined orientation on the boat, and can initiate a component handling head to pick the component if the component is not placed in the predefined orientation on the boat and initiate subsequent rotation of the turret so that the picked component is transported to the alignment means where it can be aligned again.

It will be understood that the processor may be configured to initiate any one of the above-mentioned method steps.

The turret may be configured to rotate in a first single direction to move a component from the alignment means to the loading area where the component is placed on the boat, and wherein the processor may be configured such that it can use the first image to identify if the component is in a predefined orientation on the boat, and can initiate a component handling head to pick a component which was not in a predefined orientation on the boat and initiate subsequent rotation of the turret, in the first single direction, so that the picked component is transported to the alignment means where it can be aligned again.

The processor may be configured to initiate the turret to rotate a full rotation in the first single direction after the component is picked, before the component is placed again on a boat.

The assembly may comprise a plurality of processing stations each of which can process a component, and wherein the turret is configured to rotate in a first direction to transport components between the processing stations, and wherein plurality of processing stations may be located before the loading station along the direction of rotation of the turret so that a component is processed by the plurality of processing stations before it is placed on the boat, and wherein the processor may be configured to initiate rotation of the turret in the first single direction so that the picked component is processed by the series of processing stations for a second time.

Preferably said alignment means which performs step (a) defines at least one of said processing stations.

The assembly may further comprise an alignment means, which comprises an camera which can capture an image of the component as it is held on the component handling head which is located at the processing station which comprises the alignment means; and wherein the alignment means is configured to determining based on the orientation of the component shown in an image captured by the camera how the orientation of the component should be adjusted to move the component into the predefined orientation; and an alignment arm which can receive a component from the component handling head and which can be moved to adjust the orientation of the component to move the component into the predefined orientation before the component handling head picks the component from the alignment arm.

In another embodiment the alignment arm is arranged to move the component into a predefined orientation while the component is held by the component handling head.

The assembly may further comprise a second camera which is configured to capture a second image of the boat and plurality of components, after a predefined plurality of components have been placed on the boat, and before moving the boat from the loading area.

The processor may be further configured to use the second image to determine if the plurality of components are each located at respective predefined positions on the boat. For processor may be further configured to use the second image to determine if the plurality of components form a pattern on the boat corresponding to a predefined pattern.

The processor may be configured to compare the second image to a predefined reference image, a predefined reference map, or a predefined reference pattern, which indicate the predefined positions on the boat which the plurality of components should occupy, to determine if the plurality of components are each located at predefined positions on the boat may comprise.

The processor may be further configured to identify the location of components which are not in their respective predefined locations on the boat, and initiate movement of the boat so that the identified components are consecutively aligned under component handling heads on the turret which are consecutively moved into the unloading area, to consecutively pick the identified components from the boat, and initiate rotation of the turret in a first direction so that the picked components are consecutively brought to the alignment means, if it is determined, using the second image, that one or more components are not located its/their predefined positions on the boat. In another embodiment The processor may be further configured to initiate the picking of all components from the boat, and initiate rotation of the turret in a first direction so that the picked components are consecutively brought to the alignment means, if it is determined, using the second image, that one or more components are not located its/their predefined positions on the boat.

The assembly may further comprise a testing station which can receive a boat on which one or more components have been placed; and a third camera which is located at the testing station which can capture a third image of the boat and said plurality of loaded components; and wherein the processor is further configured to use the third image to determine if a component has become displaced during the transport of the boat to the testing station.

The processor may be configured to compare the second image and the third image and identifying, based on the comparison of the second and third images, if a component has become displaced during the transport of the boat to the testing station.

In a variation of the present invention the processor may be configured to compare the third image to a predefined reference map, a predefined reference pattern or predefined reference image which indicate the positions on the boat which the plurality of components should occupy. Advantageously this variation illuminates the need for capturing the second image prior to transport.

The assembly may further comprise a guiding means which can facilitate moving a boat into a predefined position. The guiding means may be provided at the testing station to facilitate moving a boat into a predefined position required for testing. The guiding means may comprise projections (e.g. pogo pins) provided at the testing station and corresponding recesses (e.g. fiducials) provided on the boat. The guiding means may comprise markings. A further additional camera may be provided at the testing station and wherein image data captured by the additional camera is used to facilitate moving of the boat into its predefined position.

The processor may be configured to initiate returning the boat to a loading area without testing any of the components on the boat if it is determined from the third image that a component is displaced, and, the consecutive picking of all components from the boat using respective component handling heads on a turret, so as to remove all components from the boat, and, rotation of the turret in a first direction so that the picked components are consecutively brought to a station where step (a) is performed again, if it is identified that one or more components have become displaced during transport of the boat. In another embodiment processor may be configured to initiate returning the boat to a loading area without testing any of the components on the boat if it is determined from the third image that a component is displaced, and, the consecutive picking of the displaced components only from the boat using respective component handling heads on a turret, so as to remove the displaced components only from the boat, and, rotation of the turret in a first direction so that the picked components are consecutively brought to a station where step (a) is performed again, if it is identified that one or more components have become displaced during transport of the boat. In an embodiment the processor identifies the location of the displaced components using images captured by the first camera.

The testing station may further comprise electrical contacts which can be selectively moved to electrically contact electrical contacts of one or more components located on a boat which is located at the testing station, so that each component on the boat can be tested consecutively.

The assembly may further comprise an unloading station where tested components can be unloaded, wherein the unloading station comprises a fourth camera for capturing a fourth image of the boat and said plurality of loaded components at the unloading station;

and wherein the processor is configured to use the fourth image to determine if a component has become displaced during the transport of the boat from the testing station to the unloading station.

It will be understood that the loading station and unloading station may be the same stations, or may be independent stations.

The processor may be configured to compare the fourth image to the second image; and identify, based on the comparison of the second and fourth images, if a component has become displaced during the transport of the boat.

The processor may be configured to initiate use of the first camera to identify the location of displaced component for picking if a component has become displaced during the transport of the boat to the unloading station.

### BRIEF DESCRIPTION OF THE DRAWINGS

The invention will be better understood with the aid of the description of an embodiment given by way of example and illustrated by the figures, in which:

FIG. 1 shows an aerial view of a component handling assembly according to an embodiment of the present invention;

FIG. 2 shows a perspective view of the turret, first and second cameras, processor and carrier of the assembly shown in FIG. 1;

FIG. 3 shows a magnified view of the alignment means which is provided at a processing station of the component handling assembly shown in FIG. 1.

FIG. 4 shows an example of a first image captured by a first camera in the component handling assembly of FIG. 1;

FIG. 5 shows an example of a second image captured by a second camera in the component handling assembly of FIG. 1;

FIG. 6 shows an example of a reference pattern to which the second image can be compared.

### DETAILED DESCRIPTION OF POSSIBLE EMBODIMENTS OF THE INVENTION

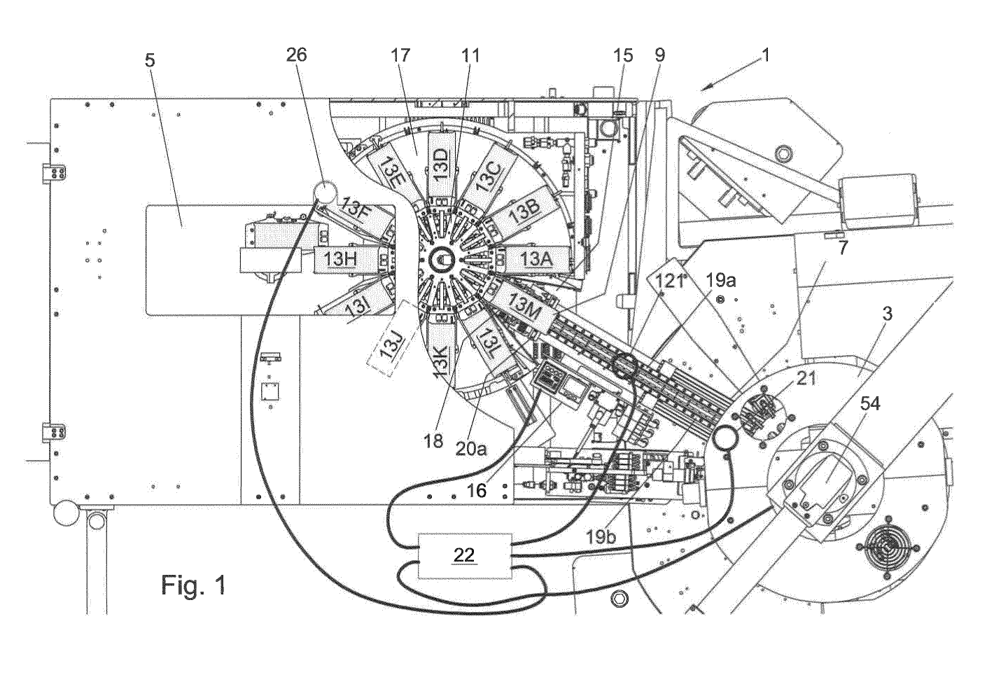

FIG. 1 shows an aerial view of a component handling assembly 1 according to an embodiment of the present invention.

The component handling assembly 1 comprises a rotatable turret 3 having a plurality of component handling heads which can be used to load components (e.g. electronic components such as LED's) onto a boat 9 located in a loading-unloading area 7 and/or which can be used to unload components (e.g. electronic components such as LED's) from a boat 9 located in the loading-unloading area 7. The rotatable turret 3 is configured such that it can be selectively rotated about rotation axis 54. In this embodiment the loading and unloading area is a single area 7, however in a variation of the invention the assembly one area where components can be loaded onto a boat and a different area where component can be unloaded from a boat; in this variation the loading and unloading of components on/from different boats may be carried out simultaneously.

The component handling assembly 1 further comprises a testing station 5 at which components which are located on the surface of a boat 9 can be tested. It will be understood that the present invention is not limited to any particular type of testing so the testing station may be have any suitable configuration to perform any type of testing on the components.

A temperature management system 17 is further provided in the component handling assembly 1. The temperature management system 17 comprises a plurality of temperature control stations 13A-J each of which can receive a boat 9. At each temperature control station 13A-J a boat 9 is either heated or cooled by cooling means and/or heating means provided at the station. A rotatable carrier 11 transports the boats from a receiving area 15, between successive temperature control stations 13A-F, into the testing station 5 where the components on the boat 9 are tested, and then between successive temperature control stations 13G-J. In this example the temperature control stations 13A-F gradually heat the boats 9 so that the components on the boats 9 are brought to a predefined temperature required for testing at the testing station 5. The temperature control stations 13G-J gradually cool the boat so that the components on the boats 9 are brought to another, cooler, predefined temperature after testing has been completed. It will be understood that the temperature management system 17 is optional; in a variation of the embodiment the component handling assembly is without a temperature management system 17.

A carrier 16 is further provided for transporting boats 9 from the loading-unloading area 7, to the receiving area 15 where the boat 9 can be picked from the carrier 16 by the rotatable carrier 11 of the temperature management system 17. In this example the carrier 16 is in the form of an x-y table 16 having a platform 18 on which a boat 9 can be supported. The platform 18 is movable along pairs of tracks 19a,b & 20a,b so that the platform can be moved in two dimensions. However it should be understood that the present invention is not limited to having a carrier 16 in the form of an x-y table; the carrier 16 may take any suitable configuration so long as it is configured so that it can move a boat 9 in more than one dimension.

FIG. 1 illustrates a boat 9, which has components loaded on its surface, located on the platform 18 of the carrier 16; and the carrier 16 has moved the boat 9 from the loading-unloading area 7 to the receiving area 15 where the boat 9 can be picked from the carrier 16 by the rotatable carrier 11 of the temperature management system 17. Furthermore a boat 9 is located at each of the respective temperature control stations 13A-J and a boat 9 is also located in at the testing station 5.

The component handling assembly 1 further comprises a first camera 21 which is arranged such that it can capture images of one or more components which have been loaded onto the surface of a boat 9 located in the loading-unloading area 7. The first camera 21 is fixed in predefined location so that the first camera 21 has a predefined field of view of a predefined area. The first camera 21 is preferably fixed at its predefined location during a calibration process which is carried out before the assembly is put into use. Specifically, the first camera 21 is fixed in location where it can capture an image of a component which has been loaded onto the surface 33 of a boat 9 in the loading-unloading area 7; and the field of view is of a size sufficient to capture and image of a single component only which has been loaded onto the surface 33 of a boat 9 in the loading-unloading area 7. Because the first camera 21 is fixed in predefined location the field of view of the first camera can be used as a reference frame, to determine if a component is correctly orientated and/or positioned on the boat 9; or a reference frame which is arranged to be visible in the field of view of the first camera 21 can be used as a reference frame, to determine if a component is correctly orientated and/or positioned on the boat 9, as will be described in more detail later.

The first camera 21 may take any suitable form; for example the first camera 21 may be a video camera which captures a video of individual components which have been loaded onto boat 9 located in the loading-unloading area 7, or may be a camera which captures still images of individual components which have been loaded onto boat 9 located in the loading-unloading area 7.

The first camera 21 is operably connected to a processor 22 so that image data captured by the first camera 21 can be sent to the processor 22. The processor 22 is further operably connected to the rotatable turret 3; the processor 22 is configured to control the rotatable turret 3 based on the image data the processor 22 receives from the first camera 21. In a further embodiment the processor 22 is further configured to control the x-y table (specifically the movement of the platform 18 along pairs of tracks 19a,b & 20a,b) based on the image data the processor 22 receives from the first camera 21.

The component handling assembly 1 additionally comprises a second camera 121 which has a wider field of view than the first camera 21.

The second camera 121 is arranged such that it can capture images of a boat 9 located in the loading-unloading area 7 or to capture images of a boat 9 which has just left the loading-unloading area 7. In this embodiment the second camera 121 is located adjacent the loading-unloading area 7 and above the tracks 19a of the carrier 16, so that the second camera 121 can to capture images of a boat 9 immediately after the boat 9 has been moved out of the unloading-loading area 7 by the carrier 16. In another embodiment the second camera 121 is located in the loading-unloading area 7 (e.g. in the loading-unloading area, above the turret 3). The second camera 121 is arranged such that it can capture an image showing all of the components which have been loaded onto the surface of the boat 9; most preferably the second camera 121 is arranged such that it can capture an image showing an aerial view of the boat 9, showing all the components 50 which are located on the surface 33 of the boat 1. The second camera 121 may also take any suitable form; for example the second camera 121 may be a video camera which captures a video of a boat 9 located in the loading-unloading area 7, or may be a camera which captures still images of a boat 9 located in the loading-unloading area 7.

The second camera 121 is operably connected to a processor 22 so that image data captured by the second camera 121 can be sent to the processor 22. The processor 22 is further configured to control the carrier 16 and the rotatable turret 3 based on the image data the processor 22 receives from the second camera 121.

Additionally the component handling assembly 1 comprises a third camera 26 which is arranged such that it can capture images of a boat 9 located at the testing station 5; specifically the third camera 26 is arranged such that it can capture an image showing all of the components on the surface of the boat 9; most preferably the second camera 121 is arranged such that it can capture an image showing an aerial view of the boat 9, showing all the components 50 which are located on the surface 33 of the boat 1. The third camera 26 is configured to have a field of view which is larger than the field of view of the first camera 21. In the most preferred embodiment the field of view of the third camera 26 has equal dimensions to the field of view of the second camera 121. The third camera 26 may take any suitable form; for example the third camera 26 may be a video camera which captures a video showing all of the components on the surface of the boat 9 located at the testing station 5, or may be a camera which captures a still image showing all of the components on the surface of the boat 9 located in the testing station 5.

The third camera 26 is further operably connected to a processor 22 so that image data captured by the third camera 26 can be sent to the processor 22. The processor 22 is further configured to control the carrier 16 and the rotatable turret 3 based on the image data the processor 22 receives from the third camera 26.

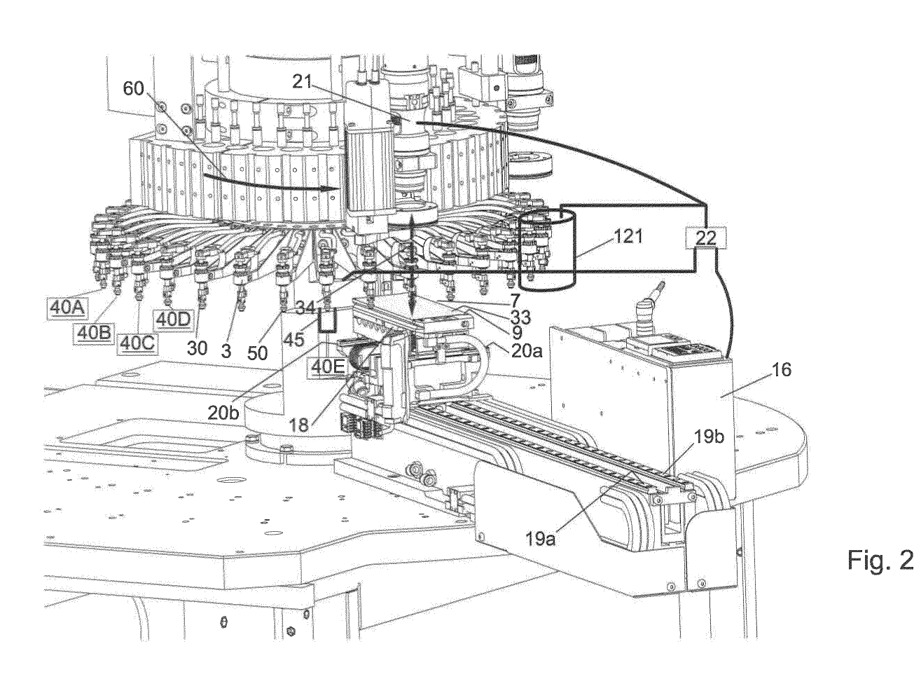

FIG. 2 provides a perspective view of the rotatable turret 3, first camera 21, second camera 121, processor 22 and carrier 16 of the component handling assembly 1 of in FIG. 1.

As can be seen in FIG. 2 the rotatable turret 3 comprises a plurality of component handling heads 30 each of which can hold a component 50. In this embodiment each component handling head 30 is configured to apply a vacuum to a component 50 so that the component 50 is held on the component handling head 30.

An empty boat 9, which is to be loaded with components 50, is shown to be located in the loading-unloading area 7. The boat 9 is shown supported on the platform 18 of the carrier 16; and the platform 18 has been moved along pairs of tracks 19a,b & 20a,b so that the boat 9 is located beneath a component handling head 30 on the turret 3 which is located in the loading-unloading area 7. Specifically the platform 18 has been moved along pairs of tracks 19a,b & 20a,b so that a predefined area on the surface 33 of the boat 9 is aligned beneath a component handling head 30 on the turret 3 which is located in the loading-unloading area 7. During operation, the component handling head 30 can extend along an axis 34, which is parallel to the axis of rotation 54 of the turret 3, to place the component 50 it holds onto said predefined area on the surface 33 of the boat 9 which is aligned beneath the component handling head 30.

A plurality of processing stations 40A-E are further provided beneath the turret 3. The processing stations 40A-E define a processing line. Each processing station 40A-E is configured to process a component in some manner and/or to test some aspect of a component. For illustration purposes the processing stations 40A-E are shown schematically and only four processing stations 40A-E are shown; however it will be understood that any number of processing stations 40A-E may be provided and that the processing stations 40A-E may take any suitable configuration. Preferably a processing station 40A-E is provided beneath each of the respective component handling heads 30 (except for the component handling head 30 located in the loading-unloading area 7). Each of the processing stations 40A-E is aligned beneath a respective component carrying head 30 so that the component carrying heads 30 on the turret 3 can extend along their respective axis 34 to deliver the component 50 it holds to a respective processing station beneath and subsequently pick the processed component 50 from the respective processing station after processing has been completed.

The turret 3 rotates in a single first direction 60 to move each respective component 50 along the series of processing stations 40A-E before moving each respective component into the loading-unloading area 7 where it is then loaded onto the surface 33 of the boat 9.

Importantly, one of the processing stations 40E comprises an alignment means 45. Preferably the processing station 40E is provided immediately preceding the loading-unloading area 7. The alignment means 45 is configured to align a component 50 into a predefined orientation. In the example shown in FIGS. 2 (and 3) the alignment means 45 is configured to receive the component from the component handling head 30 and to move the orientation of the component so that when the component 50 is picked by the component handling head 30 from the alignment means 45 again the picked component 50 will occupy the predefined orientation on the component handling head 50. In another embodiment the alignment means is configured to align the component, while the component 50 is being held on the component handling head 30 (“touchless centring”), into the predefined orientation. The predefined orientation into which the alignment means 45 moves the component is such that when the component 50 is loaded onto the surface 33 of the boat 1 the component 50 will have a predefined orientation on the surface 33 of the boat 9. The predefined orientation on the surface 33 of the boat 9 which the component 50 will have will be such that electrical contacts of the component 50 have an orientation corresponding to the orientation of electrical contacts at the a testing station 5 when the boat 9 has been moved into the test position at the testing station 5; ultimately this will allow the electrical contacts at the a testing station 5 to be moved to electrically contact the electrical contacts of the component 50 on the boat 9.

A reference frame is provided so that it appears in the field of view of the first camera 21; the reference frame defines the predefined orientation on the surface 33 of the boat 9 which a component 50 should have. The reference frame may be provided in any suitable manner, for example the reference frame may be a marker provided on a lens of the first camera 21 so that it appears in the field of view of the first camera 21; in another example an additional transparent lens which has a marker defining the reference frame may be provided to overlay the lens of the located at the center of the field of view. In one example the reference frame comprises a marker (e.g. x-marker) arrange such that it appears at the center of the field of view of the first camera 21, in another example the reference frame further comprises marker lines (e.g. a square-shaped marker, and/or rectangular-shaped marker) provided on the lens of the camera 21. A component 50 will be said to be in the predefined orientation on the surface 33 of the boat 9, if the component is centred with respect to reference frame and/or if the sides of the component 50 are parallel with markers lines which define the reference frame. In another embodiment the field of view of the first camera 21 defines a frame of reference for a component 50 which has been loaded on the boat 9; in this variation a component 50 will be said to be in the predefined orientation on the surface 33 of the boat 9, if the component is centred with respect to the field of view of the first camera 21 and if the sides of the component 50 are parallel with the edges of the field of view of the first camera 21.

For example, the component 50 may be a rectangular shape and the predefined orientation on the component handling head 30 into which the component 50 is moved by the alignment means 45 may be defined with respect to a reference axis; the component 50 is moved by the alignment means 45 so that the longitudinal axis of the component 50 is aligned with the reference axis so that the component 50 is in the predefined orientation on the component handling head 30. The turret 3 is then rotated so that the component handling head 30 is brought to the loading-unloading area 7 where the aligned component 50 is loaded onto the surface of the boat 9; since the component 50 has been aligned to a predefined orientation on the component handling head 30 by the alignment means 45, the component should then be in a predefined orientation on the surface 33 of the boat 9 when loaded onto the surface 33; more specifically component 50 should be centred with respect to reference frame which appears in the field of view of the first camera 21 and the sides of the component 50 should be parallel with linear markers which define the reference frame.

The component handling assembly can be used to implement a method according to the present invention:

A boat 1 is moved by the carrier 16 into the loading-unloading area 7. Specifically the platform 18 is moved, under the control of the processor 22, along pairs of tracks 19a,b & 20a,b so that a predefined position on the surface 33 of the boat 9 is aligned beneath a component handling head 30 on the turret 3 which is located in the loading-unloading area 7.

In an embodiment of the invention the components 50 to be loaded onto the boat are provided on a wafer and a camera is used to capture an image of components 50 on a wafer prior to the components 50 being held by the component handling heads 30 on the turret 3; from this image the arrangement of the electrical contacts on the components 50 is determined; based on the determined arrangement of the electrical contacts, and based on the arrangement of the electrical contacts at the testing station 5 (which is predefined and known by the processor 22), the processor 22 determines the predefined orientation which the component 50 should have when placed on the surface 33 of the boat 9 and tunes the alignment means 45 so that it aligns the components 50 on the component handling head 30 so that the component is that predefined orientation when placed on the surface 33 of the boat 9. The processor 22 determines the positions (e.g. the x-y position) on the surface 33 of the boat 9 which consecutively loaded components should have and tunes the x-y table so that those positions are successively aligned with the component handling heads 30 which are successively moved into the loading-unloading area 7.

The component handling head 30 which is located in the loading-unloading area 7 is then extend along an axis 34, which is parallel to the axis of rotation 54 of the turret 3, to place the component 50 it holds onto the surface 33 of the boat 9. It should be noted that the component 50 held by the component handling head 30 which is located in the loading-unloading area 7 has already undergone processing at each of the processing stations 40A-E in the assembly 1; in particular the component 50 has already been aligned by the alignment means 45 into a predefined orientation on the component handling head 30 so that when the component 50 is loaded onto the surface 33 of the boat 9 the component should occupy a predefined a predefined orientation on the surface 33 of the boat 9.

After the component 55 has been loaded onto the surface 33 of the boat 9, the processor 22 initiates the first camera 21 to capture a first image of the component 50 which was loaded onto the surface 33 of the boat 9. It should be understood that the field of view of the first camera 21 is large enough to capture an image of a single component 50 only which has been placed on the surface 33 of the boat 9.

The processor 22 then receives the first image from the first camera 21 and processes the first image to determine from the first image if the component is in the predefined orientation on the surface 33 of the boat 9. In this example the processor 22 determines if the component is in the predefined orientation on the surface 33 of the boat 9 by determining if the component 50 is centred with respect to reference frame which appears in the field of view of the first camera 21. The first image will show both the component 50 and the reference frame as both appear in the field of view of the first camera 21. As mentioned above, the reference frame may be defined by a marker which is arranged to appear at the centre of the field of view (the position of the first camera is arranged in a calibration step to have a predefined know position, thus allowing the centre of the field of view of the first camera 21 to be used as a reference); in this case the processor 22 determines that a component 50 is in its predefined orientation on the surface 33 of the boat 9 if the centre of the component 50 is aligned with the marker which appears at the centre of the field of view of the first camera 21, otherwise the component 50 will be considered to be displaced from its predefined orientation. The reference frame which appears in the field of view of the first camera 21 may take any suitable configuration, for example the reference frame may further comprise linear markers which outline the border of (or corners of) the predefined orientation for a component; in this case the sides of the component 50 are parallel with those markers which define the reference frame then the processor 22 will determine that the component 50 is in its predefined orientation otherwise the component 50 will be considered to be displaced from its predefined orientation. The reference frame is preferably defined by fiducials or markers which are provided on the lens of the first camera 21 so that they appear in the field of view of the first camera 21 (and thus appear in a first image captured by the first camera 21).

In a further embodiment of the present invention a plurality of components (preferably a predefined number of components) are loaded onto the surface 33 of the boat 9 (either simultaneously or consecutively); only after the plurality of components have been loaded onto the surface 33 of the boat 9 only then does the processor 22 initiate the first camera 21 to capture respective first images of each of the plurality of components 50 which are on the surface 33. In this further embodiment after the plurality of components have been loaded onto the surface 33 of the boat 9 the processor 22 initiates the x-y table 16 to move the boat 9 so that each of the components 50 on the surface 33 are consecutively moved into the field of view of the first camera 21 so that respective first images of each of the components 50 can be captured. The first image will show both the component and the reference frame as both appear in the field of view of the first camera 21. The processor 22 receives the respective first images from the first camera 21 either simultaneously or consecutively, and processes the first images to determine, based on the position of the component with respect to the reference frame as shown in the respective first images, if components are in their respective predefined orientations on the surface 33 of the boat 9.

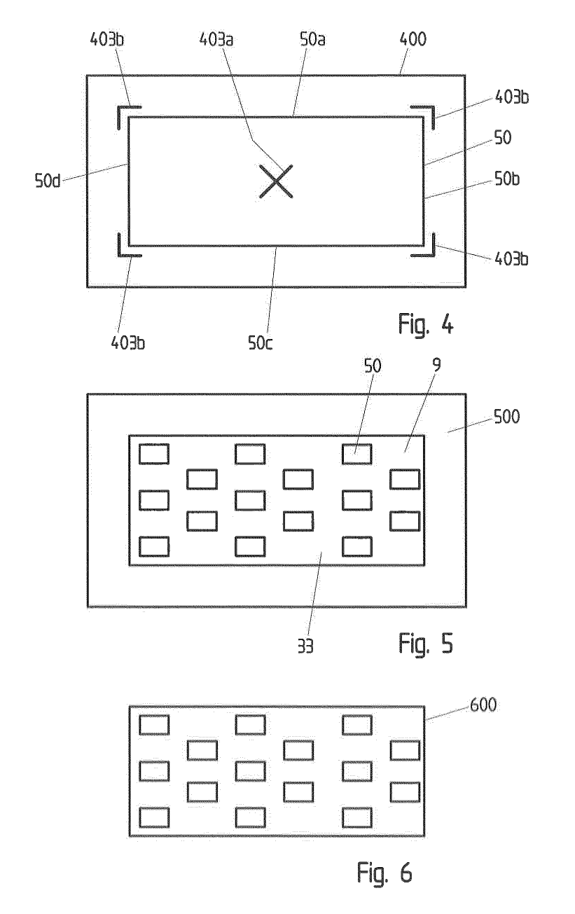

FIG. 4 illustrates an example of a first image 400 captured by the first camera 21. A reference frame 403 used to determine if the component 50 which appears in the first image 400 is in the predefined orientation on the surface 33 of the boat 9. The first image 400 shows both the component 50 and the reference frame 403 as both appear in the field of view of the first camera 21. The reference frame 403 comprises an x-marker 403a marking the centre of the field of view of the first camera 21 and linear markers in the form of fiducials 403b. The processor 22 determines if a component 50 is in the predefined orientation on the surface 33 of the boat 9 by performing image analysis on the first image 403 to determine if the component 50 shown in the first image 400 is aligned with the reference frame 403; specifically in this example the processor 22 processes the first image 400 to determine if the centre of the component 50 is aligned with the x-marker 403a, and if the sides 50a-d of the component 50 are parallel with fiducials 403b. It will be understood that the reference frame 403 is not limited to requiring fiducials 403b, in another embodiment the reference frame 403 comprises only the x-marker 403 marking the centre of the field of view of the first camera, and the processor 22 determines from the first image 400 if the component 50 is the predefined orientation simply by processing the first image 400 to determine if the centre of the component 50 is aligned with the x-marker 403a marking the centre of the field of view of the first camera 21.

FIG. 4 shows a first image 400 depicting a rectangular shaped component 50 which has been loaded onto the surface 33 of the boat 9.

The component 50 is shown to be centred with respect to reference frame 403 appearing in the image, as indicated by the centre of the component 50 being aligned with the x-marker 403a appearing in the image and the sides 50a-d of the component 50 being parallel with fiducials 403b appearing in the image; accordingly the processor 22 will determine that the component 50 is in the predefined orientation on the surface 33 of the boat 9.

As the component handling head 30 in the loading-unloading area is loading its respective component 50 onto the surface 33 of the boat 9, other components 50 which are held by other component handling heads 30 on the turret 3 are also undergoing processing at respective processing stations 40A-E. In particular at processing station 40E the alignment means 45 aligns a component 50 on the component handling head 30 which is located at processing station 40E, into a predefined orientation. The predefined orientation into which the alignment means 45 aligns the component 50 is such the component should have an orientation in which it is centred with respect to reference frame 403; specifically the centre of the component 50 is aligned with the x-marker 403a appearing in the image and the sides 50a-d of the component 50 being parallel with fiducials 403b, when the component 50 is placed on the boat 9; in other words the alignment means 45 aligns the component 50 into an orientation so that the component 50 is loaded onto the surface 33 of the boat 9 in the predefine orientation on the surface 33 of the boat 9.

If the processor determines from the first image that the component 50 which was loaded on the surface 33 of the boat 9 is not in the predefined orientation (i.e. if the centre of the component is not aligned with the x-marker 403a, and/or the sides 50a-d of the component 50 are not parallel with fiducials 403b, which define the reference frame 403), then the processor 22 initiates the component handling head 30 to extend along an axis 34, to pick the component 50 from the surface 33 of the boat 9. Once the component 50 has been picked the processor 22 initiates the turret 3 to rotate one iteration in the single first direction 60, so that the next component handling head 30 on the turret 3 which holds a component 50 which has already undergone processing at each of the processing stations 40A-E, is moved into the loading-unloading area 7. Notably the picked component is re-entered into the process line (defined by the processing stations 40A-E) when the turret 3 is rotated in the single first direction 60. Importantly in this embodiment the direction of rotation of the turret is not changed, rather the turret 3 is rotated in the single direction 60 only so the turret 3 will move the picked component 50 around the full rotation of the turret 3 so that the picked component 50 will be presented for processing, for a second time, at each of the procession stations 40A-E. In particular the picked component will be aligned by the alignment means 45 at the processing station 40E into the predefined orientation on the component handling head 30 for a second time. After the picked component 50 has been moved by the picked component 50 around the full rotation of the turret 3 the component 50 will again be returned to the loading-unloading area 7 where it will be placed by the component handling head 30 onto surface 33 of a boat 9 for a second time; and the same steps will be repeated by the processor 22 to check if the orientation of component 50 on the surface 33 of the boat 9 is equal to the predefined orientation.

If the processor determines from the first image that the component 50 which was loaded on the surface 33 of the boat 9 is in the predefined orientation on the surface 33 of the boat 9 (i.e. that the centre of the component is aligned with the x-marker 403a, and the sides 50a-d of the component 50 are parallel with fiducials 403b of the reference frame 403, as shown in FIG. 4) then the processor 22 initiates the turret 3 to rotate one iteration in the single first direction 60 so that the next component handling head 30 on the turret 3 which holds a component 50 which has already undergone processing at each of the processing stations 40A-E, is moved into the loading-unloading area 7. The processor 22 initiates movement of the platform 18 along pairs of tracks 19a,b & 20a,b so that a second predefined position on the surface 33 of the boat 9 is aligned beneath the component handling head 30 on the turret 3 which has been moved into the loading-unloading area 7. The component 50 is loaded by the component handling head 30 onto the second predefined position on the surface 33 of the boat 9. The same steps as mentioned above are carried out by the processor 22 to check if the component 50 which was loaded onto the second predefined position has an orientation on the surface 33 of the boat 9 corresponding to the predefined orientation (i.e. to check if the centre of the component is aligned with the x-marker 403a, and the sides 50a-d of the component 50 are parallel with the fiducials 403b of the reference frame 403); and the same steps as described above are carried out based on the results of that check.

These steps are repeated until a predefined number of components 50 have been loaded onto the surface 33 of the boat 9; a predefined number of components 50 are consecutively loaded onto the surface 33 of the boat 9 and the orientation of each of those components 50 checked by the processor 22 using respective first images captured for each component 50. Preferably the above-mentioned steps are repeated until the surface 33 of the boat 9 fully loaded with components 50.

In this embodiment the processor 22 initiates movement of the platform 18 along pairs of tracks 19a,b & 20a,b so that the predefined number of components are placed in a particular pattern on the surface 33 of the boat 1. The processor 22 is configured to provide the user with a plurality of selectable patterns of positions for components to occupy on the surface 33 of the boat 9; and to receive an input from the user indicating the selected pattern. The processor 22 may then initiate movement of the platform 18 along pairs of tracks 19a,b & 20a,b so that successive components 50 are placed by successive component handling heads 30 at positions corresponding to the positions defining the selected pattern. In order to achieve positioning of the components 50 on the surface 33 of the boat 9, the processor 22 initiates the platform 18 to move the boat 9 so that positions on the surface 33 of the boat 9 corresponding to the selected pattern, are successively aligned beneath component handling heads 30 which are successively moved into the loading-unloading area 7. It is clear that in this embodiment the angular orientation of the components on the boat (e.g. the angle which a longitudinal axis of the component forms with the a longitudinal axis of the boat) is achieved by the alignment means 45; and the y-x positioning of the component on the surface 33 of the boat 9 is achieved by the positioning of the x-y table (in particular the platform 18 on which the boat 9 is supported) under the component handling head 30 in the loading-unloading area 7.

After a predefined number of component 50 been loaded onto the surface 33 of the boat 9. The processor 22 initiates the second camera 121 to capture a second image showing all of the components 50 which have been loaded onto the surface 33 of the boat 9. The second image will preferably be an image showing an aerial view of the boat 9, showing all the components 50 which are located on the surface 33 of the boat 1. In this embodiment the second image is captured before the boat 9 is moved out of the loading-unloading area 7. In another embodiment the first camera 21 may alternatively be used to capture the second image; however in such an embodiment the first camera 21 needs to be adjusted to widen the field of view so that the field of view is wide enough to capture an image showing an aerial view of the boat 9, showing all the components 50 which are located on the surface 33 of the boat 1; advantageously in such an embodiment no second camera 121 is necessary to capture a second image.

FIG. 5 is an illustration of a second image 500. The second image is an aerial view of the surface 33 of the boat 9 showing the components 50 placed in a pattern on the surface 33 of the boat 9 corresponding to the pattern selected by a user. In this illustration the pattern is a pattern having alternating rows of three components 50 and two components 50.

The processor 22 uses the second image to determine if the plurality of components 50 which have been loaded into the correct positions on the surface 33 of the boat 9; specifically the processor 22 uses the second image to determine if the plurality of components 50 occupy the positions which form a pattern on the surface 33 of the boat 9 corresponding to the pattern which was selected by the user. The processor 22 compares the second image to a reference pattern (e.g. a reference matrix) corresponding to the pattern which was selected by the user; more specifically the processor 22 compares the pattern which the components are shown in the second image to form on the surface 33 of the boat 9 with a reference pattern. In an variation of the embodiment the processor 22 compares the second image to a predefined reference image showing components arranged in a pattern corresponding to the pattern which was selected by the user; or in a further variation the processor 22 compares the second image to a predefined reference map showing components arranged in a pattern corresponding to the pattern which was selected by the user.

If the positions of a threshold number (or greater) of components shown in the second image differ from a reference pattern then the processor 22 will determine that the plurality of components 50 are located at the correct positions on the surface 33 of the boat 9 (are located at their respective predefined positions on the boat 9), otherwise the processor 22 will determine that the plurality of components 50 are located at the correct positions (i.e. predefined positions) on the surface 33 of the boat 9. For example the threshold number of components may be two components; thus if the positions of at least two components shown in the second image differ from the reference pattern, then the processor 22 will determine that the plurality of components 50 are not in their respective predefined positions on the surface 33 of the boat 9 (e.g. the processor 22 will determine that the plurality of components 50 have not been loaded into the correct positions on the surface 33 of the boat 9), otherwise the processor 22 will determine that the plurality of components 50 are in their respective predefined positions on the surface 33 of the boat 9 (e.g. the processor 22 will determine that the components 50 have been loaded into the correct positions on the surface 33 of the boat 9.

In a variation of this embodiment the processor 22 compares the second image to a predefined reference image showing components arranged in a pattern corresponding to the pattern which was selected by the user. It should be noted that preferably the predefined reference image is captured under the same light conditions as the light conditions under which the second image is captured; and the second image and reference image have the same pixel density. In this variation of the embodiment a predefined threshold number of pixels may be provided; each pixel in the second image is compared to a corresponding pixel having the same position in the predefined reference image (e.g. the colour or grey value of each pixel in the second image is compared to the colour or grey value of a corresponding pixel having the same position in the predefined reference image); and if the number of pixels in the second image which are found to be different to their corresponding pixel having the same position in the predefined reference image, is greater than the predefined threshold number of pixels then the processor 22 will determine that the plurality of components 50 are not located into the correct positions (i.e. are not located at their respective predefined positions) on the surface 33 of the boat 9, otherwise the processor 22 will determine that the plurality of components 50 have located at the correct positions on the surface 33 of the boat 9 (i.e. are located at their respective predefined positions). For example the predefined threshold amount may be twenty pixels, thus if more than twenty pixels in the second image fail to match pixels which are located in a corresponding position in the predefined reference image (e.g. if the grey scale value or colour values of the pixels fail to match) then the processor 22 will determine that the plurality of components 50 are not located into the correct positions (i.e. are not located at their respective predefined positions) on the surface 33 of the boat 9, otherwise the processor 22 will determine that the plurality of components 50 are located into the correct positions (i.e. are not located at their respective predefined positions) on the surface 33 of the boat 9. The second image which is captured will also be used as a reference image which will be compared to another image which is captured when the boat returns to the loading-unloading area 7 after testing, to determine if components have become displaced during transport and/or to determine if the number of components have become displaced during transport is greater than a predefined threshold number, as will be described in more detail later.

It should be understood this description provides only some possible examples of how an image can be compared to a another image, a reference image, a reference map, and/or a reference pattern; it should be understood that any suitable image processing can be used to identify if a component is not in its predefined orientation and/or position on the surface 33 of the boat 9.

In this embodiment the first image is used to ensure that a component is placed at the correct predefined orientation on the surface 33 of the boat 9 (by checking that the centre of the component is aligned with the x-marker 403a, and/or the sides 50a-d of the component 50 are parallel with fiducials 403b which define the reference frame 403). The second image is used to check that the each of the placed components have been placed at correct positions on the surface 33 of the boat 9. For example if the boat is to be loaded with ten components, then a respective first image is used to determine if each of the ten components is in an orientation on the surface of the boat which is equal to a predefined orientation. The first images may be captured after each component is loaded onto the surface 33 of the boat 9 or all ten components may be first loaded onto the surface 33 of the boat 9 and then first images of each of the respective components are consecutively captured. After all ten components has been placed on the boat then a second image is captured showing all ten components, collectively, on the surface of the boat. The second image is used to determine if the ten components are have been placed at the correct positions on the surface of the boat i.e. to determine that the ten components form a pattern on the surface of the boat corresponding to the pattern which was selected by the user and/or to determine if any of the components have become displaced from their respective predefined orientations during the loading of the components; even though the ten components may have been placed in the correct predefined orientation on the surface of the boat on the boat 9 according to the first images captured one or more of the components may have become displaced from its loaded position during the subsequent loading of other components onto the surface of the boat. The second image can be used to identify that the component has become displaced from the position in which it was loaded as the pattern which the components are shown in the second image to form will not be equal to the pattern selected by the user due to the displaced the component.

The step of using the second image to determine if the plurality of components are each located at predefined positions on the boat may comprise comparing the second image to a predefined reference image, a predefined reference map, or a predefined reference pattern, which indicate the positions on the boat which the plurality of components should occupy. If the second image does not match the reference image, or if the locations which the components occupy do not correspond to the locations illustrated on predefined reference map, of if the pattern formed by the plurality of components on the boat does not match the predefined reference pattern, then it can be determined that one or more components is/are not located at its/their predefined positions on the boat.

FIG. 6 shows an example of a predefined reference image 600 showing component arranged in a pattern (selected by the user) on the surface 33 of the boat 9. The processor 22 compares the reference image 600 to the second image 500 to determine if the plurality of components are each located at predefined positions on the surface 33 of the boat 9. It should be noted that preferably the predefined reference image 600 is captured under the same light conditions as the light conditions under which the second image 500 is captured; and the second image 500 and reference image 600 have the same pixel density. In this each pixel in the second image 500 is compared to a corresponding pixel having the same position in the predefined reference image 600 (e.g. the colour or grey value of each pixel in the second image is compared to the colour or grey value of a corresponding pixel having the same position in the predefined reference image); and if the number of pixels in the second image 500 which are found to be different (e.g. different grey values or colours) to their corresponding pixel having the same position in the predefined reference image, is greater than a predefined threshold number of pixels then the processor 22 will determine that the plurality of components 50 are not located at predefined positions on the surface 33 of the boat 9 corresponding to the pattern shown in the predefined reference image 600, otherwise the processor 22 will determine that the plurality of components 50 a located at their respective predefined positions corresponding to the pattern shown in the predefined reference image 600. In another embodiment the processor 22 may overlay the predefined reference image 600 on the second image 500 or superpose the predefined reference image 600 on the second image 500, to compare the second image 500 with the reference image 600; if the components shown in the images 500,600 do not align when the images are overlaid or superimposed then the processor 22 will determine that the plurality of components 50 are not located at predefined positions on the surface 33 of the boat 9 corresponding to the pattern shown in the predefined reference image 600, otherwise the processor 22 will determine that the plurality of components 50 a located at their respective predefined positions corresponding to the pattern shown in the predefined reference image 600.

If the processor 22 determines that one or more of the components 50 (or that threshold number or above of components) do not occupy their respective predefined position on the boat (i.e. if the pattern shown in the second image 500 does not match the pattern of the reference image 600) the processor 22 initiates the turret 3 and component handling heads 30 to consecutively pick all components 50 from the boat 1. Specifically the processor 22 will initiate an empty component handling head 30 located in the loading-unloading area 7 to extend along its respective axis 34 to pick a component 50 from the surface 33 of the boat 9. After the component handling head 30 has picked a component 50 the processor 22 will then initiate the turret 3 to rotate in the single first direction 60 so that the picked component 50 is re-entered into the processing line (defined by the processing stations 40A-E) and so that the next empty component handling head 30 is moved into the loading-unloading area 7 where it can pick another component 50 from the boat 9. These steps are repeated so that all components 50 are picked from the surface 33 of the boat 1 and are re-entered into the processing line. Importantly the direction of rotation of the turret 3 is not changed, rather the turret 3 is rotated in the single first direction 60 only; thus the turret 3 will move the picked components 50 around the full rotation of the turret 3 so that each of the picked component will be presented for processing, for a second time at each of the procession stations 40A-E. Thus, each of the picked components will be aligned at the processing station 40E into the predefined orientation on the component handling heads 30. In another embodiment if the processor 22 determines that one or more of the components 50 (or that threshold number or above of components) do not occupy their respective predefined position on the boat then the only those components which do not occupy their respective predefined position on the boat are picked and re-entered into to the processing line (i.e. those components which are in the respective predefined positions are not picked).

After a picked component 50 has been moved around the full rotation of the turret 3 the component 50 will again be returned to the loading-unloading area 7 where it can placed by the component handling head 30 for a second time onto the surface 33 of the boat 1. It will be understood that the processor 22 will check that each component 50 is placed in its predefined orientation using new first images captured by the first camera 21, and a subsequently a new second image, captured by the second camera 121, will be used by the processor 22 to determine that the components have been loaded onto respective predefined positions on the surface of the boat (e.g. to determine if the components have been placed in a pattern on the surface of the boat corresponding to the pattern which was selected by the user).

If the processor 22 determines from a second image that each of the components 50 which have been loaded onto the surface 33 of the boat are each located at their respective predefined positions on the boat 9 (e.g. if the processor determines from the second image that the component 50 have been correctly placed in the pattern selected by the user), the processor 22 initiates the carrier 16 to transport the boat towards the testing station 5. Specifically in this example the processor 22 initiates the carrier 16 to transport the boat 9 towards the temperature management system 17 which in turn passes the boat 9 to the testing station 5. However it should be understood that the present invention is not limited to requiring a temperature management system 17; in a variation of the embodiment no temperature management system 17 is provided and the carrier 16 is configured so that it can transport boats 9 from the loading-unloading area 7 directly to the testing station 5.

In another embodiment the predefined number of components (e.g. plurality of components) are first all loaded onto the surface 33 of the boat 9 without taking any first image of the components using the first camera 21. After the predefined number of components have been loaded onto the surface 33 of the boat 9 the second camera 121 is then used to capture a second image (i.e. an image showing an aerial view of the boat 9, showing all the components 50 which are located on the surface 33 of the boat 1). The processor 22 then compares the second image to a predefined reference image, a predefined reference map, or a predefined reference pattern, in the same manner as described above, to determine if all of the loaded components are in their respective predefined positions on the surface 33 of the boat 9. If the processor 22 determined that all the components are in their respective predefined positions then it initiates the carrier 16 (e.g. the x-y table) to transport the boat to the testing station. If however, the processor 22 determines from the second image that one or more of the components are not in their respective predefined positions, then the processor 22 initiates the first camera 21 to capture a first image of each of the components on the surface 33 of the boat 9; specifically the processor 22 initiates the x-y table to move the boat 9 so that each of the components on the surface 33 of the boat 9 are consecutively brought into the field of view of the first camera 21. For each component the processor 22 compares the position of the component with respect to the frame of reference (which appears in the field of view of the first camera 21) as shown in the first image, to identify which of the components are displaced from their predefined orientation (in the same manner described above). Once processor 22 has identified the components which are displaced from their predefined orientation the processor 22 initiates the x-y table to move so that the identified displaced components are presented for picking to consecutive component handling heads which are consecutively moved into the loading-unloading area 7 by rotation of the turret. The picked components are re-entered into the processing line where there are realigned by the alignment means 45 once again. Thus in this variation of the invention the second image is captured first using the second camera 121, and importantly the first camera 21 is only initiated to capture a first image only if the processor 22 determines from the second image that one or more components is/are not at its predefined position of the surface 33 of the boat 9.

Once the boat 9 reaches the testing station 5 the processor 22 initiates the third camera 26 to capture a third image showing all of the components 50 which located on the surface 33 of the boat 9. The third image will preferably be an image showing an aerial view of the surface 33 of the boat 9, showing all the components 50 which are located on the surface 30 of the boat 1. (The third image is similar to the second image 500 shown in FIG. 5).

The boat may be aligned into a predefined position at the testing station 5 prior to capturing the third image. A guiding means may be used to facilitate moving the boat into a predefined position at the testing station 5. For example the boat 9 may be aligned into a predefined position at the testing station 5 by arranging the boat 9 so that projections (e.g. pogo pins) at the testing station 5 are received into recesses (e.g. fiducials) on the boat 9, or vice-versa. The guiding means may take other forms such as markings etc.

The processor 22 then uses the third image to determine if a component 50 (or that threshold number or above of components) has become displaced during the transport of the boat 9 from the loading-unloading area 7 to the testing station 5. In this embodiment the processor 22 uses the third image to determine if a component has become displaced during the transport of the boat 9 by comparing the third image to the second image which was captured by the second camera 121 before the boat 9 was moved by the carrier 16 from the loading-unloading area 7. The processor 22 then determines if a component has become displaced during the transport of the boat 9 to the testing station 5 based on the comparison of the third and second images; for example the processor 22 determines a component has become displaced during the transport of the boat 9 to the testing station 5 if the positions of the components in both images are different. The processor 22 may overlay the second and third images and if one or more corresponding components shown in the respective images are off set from one another by an amount greater than a predefined threshold amount, then the processor 22 will determine that a component has become displaced during the transport of the boat 9 to the testing station 5. Preferably the third image is captured under the same light conditions as the light conditions under which the second image was captured; and the second image and third image have the same pixel density. In a variation of the invention in order determine that a component has become displaced during the transport of the boat 9 to the testing station 5 the processor 22 may compare each pixel in the third image to each pixel in the corresponding position in the second image (e.g. the colour or grey value of each pixel in the third image is compared to the colour or grey value of a corresponding pixel having the same position in the second image); but if the number of pixels in the third image which do not match the pixel at the corresponding position in the second image, is greater than a predefined threshold number of pixels then the processor 22 will determine that an unacceptable number of components 50 have become displaced during the transport of the boat 9 to the testing station 5. For example the predefined threshold amount may be twenty pixels, thus if more than twenty pixels in the third image fail to match pixels of the second image which are located in corresponding position in the second image (e.g. if more than twenty pixels in the third image fail have different grey values or colours to pixels of the second image which are located in corresponding position in the second image) then the processor 22 will determine that an unacceptable number of components 50 have become displaced during the transport of the boat 9 to the testing station 5 (e.g. the processor 22 will determine that a component has become displaced during the transport of the boat 9 to the testing station 5 and/or the processor 22 will determine that the number of components which have become displaced during the transport of the boat 9 to the testing station 5 is above a threshold value); otherwise the processor 22 will determine that the components 50 have not been displaced during transport (e.g. the processor 22 will determine that no component has become displaced during the transport of the boat 9 to the testing station 5 and/or the processor 22 will determine that the number of components which have become displaced during the transport of the boat 9 to the testing station 5 is below the threshold value).

In a variation of the embodiment the processor 22 may be configured to use the third image to determine if a component ((or that threshold number or above of components) has become displaced during the transport of the boat by comparing the third image to a predefined reference map, a predefined reference pattern or predefined reference image which indicate the positions on the boat which the plurality of components should occupy. Advantageously this variation eliminates the need for capturing the second image prior to transport.

In another embodiment the processor 22 determines if the number of components which have become displaced during the transport of the boat 9 to the testing station 5 is above a threshold value. For example the processor 22 may compare the third and second images, and determine if the number of components having different positions in the third and second images is above a threshold value.

If the processor 22 determines from the comparison of the second and third images that one or more components 50 (or that threshold number or above of components) have become displaced during transport of the boat 9 to the testing station 5 (or that the number of components which have become displaced is above a threshold level), then the processor 22 initiates the carrier 16 to return the boat 1 to the loading-unloading area 7 without testing of any components 50 on the boat 9 at the testing station. Once returned to the loading-unloading station 7 the processor 22 initiates the turret 3 and its component handling heads 30 to pick all components from the boat 9 using respective component handling heads 30 on a turret 3. In another embodiment only the displaced components are picked. For each component 50 which is picked the processor 22 initiates the turret 3 to rotate in the single first direction 60 so that picked component 50 is re-entered into the process line (defined by the processing stations 40A-E) when the turret 3 is rotated. Importantly the turret 3 is rotated in the single first direction 60 only so the turret 3 will move the picked component 50 around the full rotation of the turret 3 so that the picked component 50 will be presented for processing once again, at each of the procession stations 40A-E. In particular each of the picked components 50 will be aligned for again at the processing station 40E into the predefined orientation. Each picked component 50 will been move around a full rotation of the turret 3 and will be returned to the loading-unloading area 7 where it will be placed by the component handling head 30 onto surface 33 of the boat 1 once again, and the above-mentioned steps including capturing first and second images etc. are performed again.

If the processor 22 determines from the comparison of the second and third images that no component 50 has become displaced during transport of the boat 9 to the testing station 5 (or that the number of components which have become displaced is below a threshold level), then the processor 22 initiates the testing station 5 to carry out testing of the components 50 on the boat 9. To test the components at the testing station 5, for example, the testing station 5 may be configured to move electrical contacts of the testing station 5 into electrical contact with electrical contacts of components 50 on the boat 9; and electrical signals which implement testing may be sent to the components 50 via the electrical contacts. The components may be LED's and testing station may perform electrical testing and/or optical testing of the LED's.

In a variation of the invention the processor 22 may initiate the third camera 26 to capture both, an image showing an aerial view of the boat 9 showing all the components 50 which are located on the surface 33 of the boat 1, before the boat 9 enters the testing station 5, and another image showing an aerial view of the boat 9 showing all the components 50 which are located on the surface 33 of the boat 1, after the boat 9 exits the testing station 5 after testing has been completed. Both images are preferably captured under the same light conditions and have the same pixel density. The processor 22 can compare both images to determine if a component has become displaced during testing (e.g. by comparing that the pixels in one image with pixels in a corresponding position in the other image; if all corresponding pixels are equal (i.e. equal colour or grey value) then it can be determined that no component has become displaced during testing; if one or more corresponding pixels are not equal (i.e.do not have equal colour or grey value) then it can be determined that a component has become displaced during testing. It will be understood that any suitable image analysis can be used to compare both images.

The boat 9 may be aligned into a predefined position at the testing station 5 prior to performing testing of the components 50 on the boat. A guiding means may be used to facilitate moving the boat into a predefined position at the testing station 5. For example the boat 9 may be aligned into a predefined position at the testing station 5 by arranging the boat 9 so that projections (e.g. pogo pins) at the testing station 5 are received into recesses (e.g. fiducials) on the boat 9, or vice-versa. The guiding means may take other forms such as markings etc. Images captured by the third camera may be used to facilitate moving of the boat into the predefined position at the testing station 5.

After testing of the component 50 has been performed at the testing station 5, the processor 22 initiates the carrier 16 to transport the boat 9 on which the tested components are supported, back to the loading-unloading station 7 where the tested components 50 can be unloaded by the component handling heads 30 on the turret 3.

Before any of the tested components 50 are unloaded from the boat 9, the processor 22 initiates the second camera 121 to capture a fourth image of the boat 9 showing all of the tested components 50 which located on the surface 33 of the boat 9. The fourth image will preferably be an image showing an aerial view of the boat, showing all of the tested components 50 which are located on the surface 30 of the boat 1.

The processor 22 uses the fourth image to determine if a tested component 50 (or if threshold number or above of tested components) has become displaced during the transport of the boat from the testing station 5 to the loading-unloading area 7. In this embodiment the processor 22 uses the fourth image to determine if a tested component has become displaced during the transport of the boat 9 from the testing station 5 to the loading-unloading area 7 by comparing the fourth image to the second image which was captured by the second camera 121 before the boat 9 was moved by the carrier 16 from the loading-unloading area 7. For example the processor 22 determines a component has become displaced during the transport of the boat 9 from the testing station 5 to the loading-unloading area 7 if the positions of the components shown in the fourth and second images are different. The processor 22 may overlay the second and fourth images and if one or more corresponding components shown in the respective images are off set from one another by an amount greater than a predefined threshold amount, then the processor 22 will determine that a tested component has become displaced during the transport of the boat 9 from the testing station 5 to the loading-unloading area 7. Preferably the fourth image is captured under the same light conditions as the light conditions under which the second image was captured; and the second image and fourth image have the same pixel density. In a variation of the invention in order determine that a component has become displaced during the transport of the boat 9 from the testing station 5 to the loading-unloading area 7, the processor 22 may compare each pixel in the fourth image to each pixel in the corresponding position in the second image (e.g. compare the colour or grey value of each pixel in the fourth image to the colour or grey value of a corresponding pixel having the same position in the second image); but if the number of pixels in the fourth image which do not match the pixel at the corresponding position in the second image, is greater than a predefined threshold number of pixels then the processor 22 will determine that an unacceptable number of components 50 have become displaced during the transport of the boat 9 from the testing station 5 to the loading-unloading area 7. For example the predefined threshold amount may be twenty pixels, thus if more than twenty pixels in the fourth image fail to match pixels of the second image which are located in corresponding position in the second image (e.g. if grey value or colour of more than twenty pixels in the fourth image fail to match the grey value or colour of corresponding pixels of the second image) then the processor 22 will determine that an unacceptable number of components 50 have become displaced during the transport of the boat 9 from the testing station 5 to the loading-unloading area 7 (e.g. the processor 22 will determine that a component has become displaced during the transport of the boat 9 from the testing station 5 to the loading-unloading area 7; and/or the processor 22 will determine that the number of components which have become displaced during the transport of the boat 9 from the testing station 5 to the loading-unloading area 7 is above a threshold value); otherwise the processor 22 will determine that the components 50 have not been displaced during the transport of the boat 9 from the testing station 5 to the loading-unloading area 7 (e.g. otherwise the processor 22 will determine that no component has become displaced during the transport of the boat 9 from the testing station 5 to the loading-unloading area 7 and/or the processor 22 will determine that the number of components which have become displaced during the transport of the boat 9 from the testing station 5 to the loading-unloading area 7 is below the threshold value).

In a variation of the embodiment the processor 22 may be configured to use the fourth image to determine if a component (or that threshold number or above of components) has become displaced during the transport of the boat from the testing station 5 to the loading-unloading area 7 by comparing the fourth image to a predefined reference map, a predefined reference pattern or predefined reference image which indicate the positions on the boat which the plurality of components should occupy. Advantageously this variation eliminates the need for capturing the second image prior to transport.

If the processor 22 determines using the fourth image that a tested component (or a threshold number of tested components) has become displaced during the transport of the boat 9 from the testing station 5 to the loading-unloading area 7, then a number of different actions may then be initiated by the processor 22:

The most preferred action is that the location of the tested component(s) which has/have become displaced is identified. The processor 22 then initiates movement of the x-y table so that an identified displaced component is centered under an empty component carrying head 30 on the turret which is located in the loading-unloading area 7. Specifically the processor 22 subsequently moves the platform 18 along the along pairs of tracks 19a,b & 20a,b so that the determined locations on the boat 1 of the displaced tested components 50 are consecutively aligned under component handling heads 30 which are consecutively moved into the loading-unloading area 7 by rotation of the turret 3, so that the displaced tested components can be unloaded from the boat 9.

The processor 22 then initiates the empty component handling head 30 to extend along its respective axis 34 to pick the displaced tested component 50 from the surface 33 of the boat 9. After the component handling head 30 has picked a tested component 50 the processor 22 will then initiate the turret 3 to rotate in the single first direction 60 so that the picked tested component 50 is re-entered into the processing line (defined by the processing stations 40A-E) and so that the next empty component handling head 30 is moved into the loading-unloading area 7 where it can pick another displaced tested component 50 from the boat 9. These steps are repeated so that all displaced tested components 50 are picked from the surface 33 of the boat 1 and are re-entered into the processing line. Importantly the direction of rotation of the turret 3 is not changed, rather the turret 3 is rotated in the single first direction 60 only; thus the turret 3 will move the picked tested components 50 around the full rotation of the turret 3 so that each of the picked tested components will be presented for processing at each of the procession stations 40A-E. Thus, each of the picked tested components will be aligned by the alignment means 45 at the processing station 40E into the predefined orientation on the component handling heads 30 once again. After a picked tested component 50 has been moved around the full rotation of the turret 3 the tested component 50 will again be returned to the loading-unloading area 7; the processor 22 will initiate movement of the x-y table so that that the vacant position which was once occupied by one of the displaced testing components which has been picked, is centered under the tested component 50 which has been returned to the loading-unloading area 7; the processor 22 then initiates the component handling head 30 to extend so that it can load the tested component 50 onto the surface 33 of the boat 1. These steps are carried out for all of the displaced tested components which are picked. It will be understood that the processor 22 will check that each tested component 50 is placed in a predefined orientation on the boat using new first images captured by the first camera 21, and a subsequently using a new second image captured by the second camera 121, so as to determine if the tested components now all occupy their respective predefined positions on the surface of the boat.

The processor 22 may determine the locations of the displaced tested components from the fourth image by comparing the fourth image with the second image (and/or to the third image); and identifying which components shown in the fourth image occupy different positions to the positions which they are shown to occupy in the second and/or third image.

In one embodiment in order to determine the location of the tested component(s) which has/have become displaced the processor will initiate the x-y table to move each of the components, consecutively, into the field of view of the first camera, and respective first images area captured of each of the components. The positioning of each of the components with respect the frame of reference which appears in the field of view of the first camera 21, as shown in a first image, is then determined by the processor 22. If a component is shown in the first image to be centred with respect to reference frame (and optionally, if the sides of the component 50 are parallel with markers which define the reference frame) then the component will be considered not be displaced. If however the component is shown in the first image to be offset with respect to reference frame i.e. not centred) (and optionally, if the sides of the component 50 are not parallel with markers which define the reference frame) then that component will be considered be displaced.

In a further embodiment the distance which each of the displaced tested component(s) has/have become displaced is measured and the measured distance is compared to a threshold displacement distance. The displaced tested component is then only picked if the measured displacement of the tested component is greater than the threshold displacement distance.

Another possible action that the processor 22 may initiate if it determined using the fourth image that a tested component (or a threshold number of tested components) has become displaced during the transport of the boat 9 from the testing station 5 to the loading-unloading area 7, is that the processor 22 may initiate the turret 3 and component handling heads 30 to consecutively pick all tested components 50 from the boat 1 (including those tested components which have not been displaced). Specifically the processor 22 may initiate an empty component handling head 30 located in the loading-unloading area 7 to extend along its respective axis 34 to pick a tested component 50 from the surface 33 of the boat 9. After the component handling head 30 has picked a tested component 50 the processor 22 will then initiate the turret 3 to rotate in the single first direction 60 so that the picked tested component 50 is re-entered into the processing line (defined by the processing stations 40A-E) and so that the next empty component handling head 30 is moved into the loading-unloading area 7 where it can pick a tested component 50 from the boat 9. These steps are repeated so that all tested components 50 (including those which were not displaced) are picked from the surface 33 of the boat 1 and are re-entered into the processing line. Importantly the direction of rotation of the turret 3 is not changed, rather the turret 3 is rotated in the single first direction 60 only; thus the turret 3 will move the picked tested components 50 around the full rotation of the turret 3 so that each of the picked tested components will be presented for processing at each of the procession stations 40A-E. Thus, each of the picked tested components will be aligned at the processing station 40E into the predefined orientation on the component handling heads 30 once again. After a picked tested component 50 has been moved around the full rotation of the turret 3 the tested component 50 will again be returned to the loading-unloading area 7 where it can placed by the component handling head 30 again onto the surface 33 of the boat 1. It will be understood that the processor 22 will check that each tested component 50 is placed in a predefined orientation on the boat using new first images captured by the first camera 21, and a subsequently using a new second image captured by the second camera 121, so as to determine that the tested components have been loaded onto respective predefined positions on the surface of the boat.

In other words in one embodiment only the tested components which are identified using first images as being displaced are picked and transported around the turret to be processed and realigned at the alignment station; in a variation of this embodiment a displaced tested component is picked and transported around the turret to be processed and realigned at the alignment station only if the amount which the tested component is displaced is larger than a predefined displacement threshold; and in another embodiment all tested components (including displaced tested components and tested components which are not displaced) are picked and transported around the turret to be processed and realigned at the alignment station.

In a further embodiment each of the boats in the component handling assembly will comprise an identifier (e.g. a 2-D matrix code). The identifier will have position information associated with it; the position information will outline the predefined orientations and positions on the surface 33 of the boat 9 for components. When a boat 9 is moved into the loading-unloading area 7, the processor 22 initiates the first camera 21 to capture an image of the identifier; the processor 22 then reads the identifier shown in the image captured from the first camera 21 and the processor 22 retrieves the position information associated with that identifier (for example the identifier may indicate an address in a memory; position information detailing the predefined positions and orientations for components on the boat may be stored at the address; when the processor reads the identifier it then retrieves the position information at the corresponding memory address); the processor 22 will thus know the predefined orientations and positions for components which are to be loaded onto the boat. The processor 22 can then operate the alignment means 45 and the movement of the x-y table so that the components are loaded in the predefined orientations and positions on the surface 33 of the boat 9 as indicated in the retrieved position information. Likewise after the components have been tested at the testing station 5 the boat is transported back to the loading-unloading area 7 where the processor 22 again initiates the initiates the first camera 21 to capture an image of the identifier; the processor 22 then reads the identifier shown in the image captured from the first camera 21 and the processor 22 retrieves the position information associated with that identifier; the processor then knows the predefined orientations and positions which the tested components on the boat should have and uses that information to identifying if the components have become displaced during transport.

In a variation of the invention the assembly will comprise a first camera 21 only. When a boat enters the loading-unloading area 7 the processor 22 initiates the first camera 21 to capture an image of the identifier; the processor 22 reads the identifier shown in the image so that the processor 22 can obtain the position information associated with that identifier; the processor 22 then knows the predefined orientations and positions which the components on the boat should have. After the predefined number of components 50 have been loaded onto the boat the processor 22 initiates the first camera 21 to capture respective first images of each of the components on the boat 9 and uses the respective first images to determine if each of the components are in their respective predefined orientations and positions as specified in the position information which was associated with the identifier. For example if the first camera captures a first image of a position on the surface 33 of the boat 9 where a component should be (according to the position information associated with the identifier), and if the first image shows that there is no component present at that position, then it can be determined that the components are not in their predefined positions and orientations on the boat. Or if a first image of a component shows that the component is offset from the reference frame then it can be determined that that component is not in its predefined orientation and position. If the processor determines that a component is not in its predefined orientation and position on the boat then the processor 22 may initiate the component handling heads to pick the component and that component is re-entered into the processing line where it is aligned again by the alignment means. When all components on the boat are determined by the processor 22 to be in their respective predefined orientation and positions on the surface of the boat, then the processor 22 initiates the x-y table to transport the boat to the testing station. When the boat returns to the loading-unloading area 7 from the testing station after testing the processor 22 may again initiate the first camera 21 to capture an image of the identifier; the processor 22 reads the identifier shown in the image so that the processor 22 can obtain the position information associated with that identifier; the processor 22 then knows the predefined orientations and positions which the tested components on the boat should have. The processor then again initiates the first camera 21 to capture an image of each of the components on the boat and uses the first images to determine if any of the tested components has become displaced from their respective predefined orientations and positions during transport or testing.

In all of the above-mentioned embodiments and variations it should be understood that a vacuum may be applied to component(s) on the surface 33 of the boat 9 to hold the components on the surface 33. The vacuum may be applied to components 50 on the surface 33 of the boat 9: as components 50 are being loaded onto the surface 33 of the boat 9; as components 50 are being unloaded from the surface 33 of the boat 9; and/or as the boat 1 is being transported by the carrier 16.

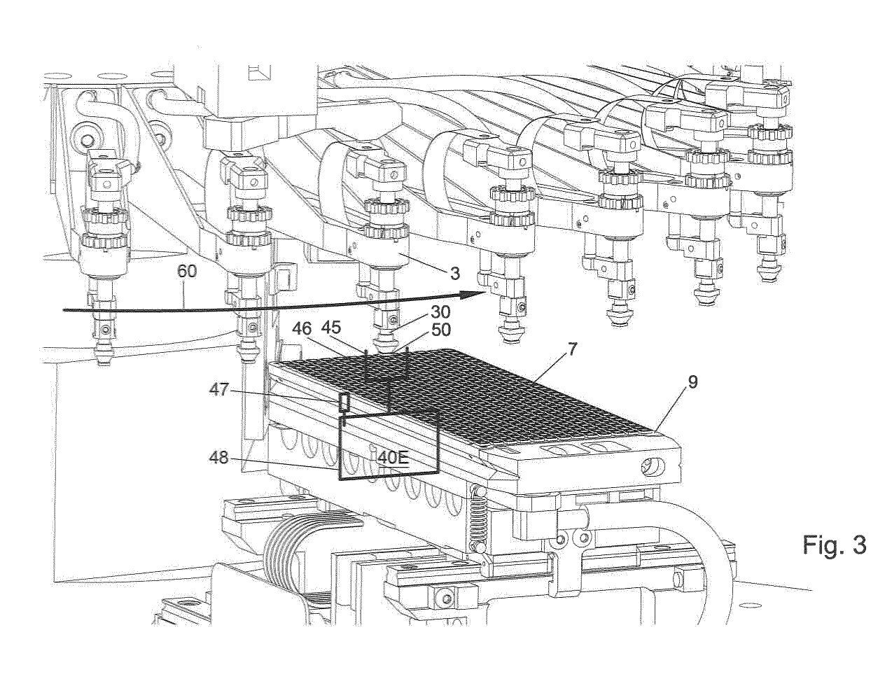

FIG. 3 provides a perspective view of the alignment means 45 which is provided at processing station 40E. The alignment means is provided adjacent the loading-unloading area 7 so that the components are aligned into a predefined orientation on the component handling head 30 immediately prior to being moved into the loading-unloading area 7 (i.e. there are no processing stations between the processing station 40E and the loading-unloading area 7 along the first direction of rotation 60). Importantly the predefined orientation on the component handling head 30 into which the alignment means 45 aligns the components 50 is such that when placed on the surface 33 of the boat 9 by the component handling head 30 the component should be in predefined orientation on the surface 33 of the boat 9. (It is understood that there are two predefined orientations for the component in this case: firstly a predefined orientation on the component handling head 30 and secondly predefined orientation on the surface 33 of the boat 9). The alignment means 45 comprises a camera 47, a controller 48 and a moving means 46 in the form of a positioning arm 46. The camera 47 is arranged to capture images of a component 50 which is held by a component handling head 30 which is located at the processing station 40E. The controller 48 is operable connected to the positioning arm 46 and camera 47 so that the controller 48 can receive image data captured by the camera 47 and can actuate the positioning arm 46 to move the component 50.

In order to move the component 50 into a predefined orientation the camera 47 captures an image(s) (e.g. a video) of a component 50; the controller determines from the image(s) the orientation of the component 50 on the component handling head 30 and determines how the component 50 must be moved in order to position the component in the predefined orientation on the component handling head 30. The component handling head 30 which is located at the processing station 40E releases the component 50 which it carries into the positioning arm 46 so that the component 50 is held exclusively by the positioning arm 46. The positioning arm 46 is then operated by the controller 48 to move component 50 based on the movement required in order to position the component in the predefined orientation, as previously determined by the controller 48 based on the images captured by the camera 47. After the positioning arm 46 has moved the component 50, the component handling head 30 then picks the component 50 from the positioning arm 46; the component 50 will then occupy a predefined orientation on the component handling head 30 once picked. The predefined orientation on the component handling head 30 into which the component 50 is moved is so that when the component handling head 30 places the component 50 on the surface 30 of the boat 9 the component 50 will be arranged in a orientation on the surface 33 of the boat 9.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. A method of handling components, the method comprising the steps of:
(a) aligning a component into a predefined orientation using an alignment means;
(b) placing the component onto a predefined position on a boat which is located in a loading area;
(c) capturing a first image of the component after it has been placed on the boat with a first camera;
(d) using the first image to identify if the component is in a predefined orientation on the boat;
(e) if the component is not in said predefined orientation on the boat, then picking the component from the boat and aligning the component again using said alignment means.

2. A method according to claim 1 wherein the step of using the first image to identify if the component is in the predefined orientation on the boat comprises comparing the component with a reference frame which appears in the first image.

3. A method according to claim 1 wherein the method comprises the step of,
moving a component from a station where step (a) is performed to a station where step (b) is performed by rotating, in a first direction, a rotatable turret, which has a handling head which holds the component; and
wherein the step of picking the component from the boat if the component is not in said predefined orientation on the boat is performed by a component handling head on the rotatable turret; and
wherein the method further comprises the step of rotating the turret in said first direction after the component has been picked to bring the picked component to the station where step (a) is performed again.

4. A method according to claim 1, wherein the method comprises the step of moving a component between a series of processing stations by rotating, in a first direction, a rotatable turret, which has a handling head which holds the component, before performing steps (b)-(e) at least, and wherein the method further comprises the step of passing a picked component through the series of processing stations for a second time after it has been picked.

5. A method according to claim 1, wherein the method further comprises, repeating steps (b)-(e) on the component which was picked and aligned again.

6. A method according to claim 1, wherein the step of aligning an component into a predefined orientation using an alignment means comprises,
using a camera to capture an image of the component held on the component handling head and using that image to identify the orientation of the component held on the component handling head;
determining based on the orientation of the component shown in the image how the orientation of the component should be adjusted to move the component into the predefined orientation;
transferring the component from the component handling head to an alignment arm of an alignment means;
adjusting, using the alignment arm, the orientation of the component by the determined amount to move the component into the predefined orientation,
picking the component from the alignment arm using the component handling head.

7. A method according to claim 1, wherein the method comprises the steps of,
repeating steps (a)-(e) until a predefined plurality of components are on the boat;
capturing a second image of the boat and plurality of components, after the predefined plurality of components have been placed on the boat and before moving the boat from the loading area.

8. A method according to claim 7 wherein the method comprises the step of,
using the second image to determine if the plurality of components are each located at predefined positions on the boat.

9. A method according to claim 8 wherein, if it is determined, using the second image, that one or more components are not located in its/their predefined position(s) on the boat, then, either,
consecutively picking all components from the boat using respective component handling heads on the turret, so as to remove all components which were placed on the boat, and rotating the turret in a first direction so that the picked components are consecutively brought to a station where step (a) is performed again; or
identifying the positions of the one or more components are not located in its/their predefined position(s) on the boat, and consecutively picking said one or more components only from the boat using respective component handling heads on the turret, so as to remove said one or more components which were placed on the boat, and rotating the turret in a first direction so that the picked components are consecutively brought to a station where step (a) is performed again.

10. A method according to claim 1, wherein the method further comprises the steps of,
transporting the boat to a testing station where the components on the boat are to be tested;
capturing a third image of the boat and said components which have been placed on the boat;
using the third image to determine if one or more component(s) has/have become displaced during the transport of the boat to the testing station.

11. A method of claim 10 when dependent claim 7, wherein the step of using the third image to determine if a component has become displaced during the transport of the boat comprises,
comparing the third image and the second image;
identifying, based on the comparison of the third and second images, if one or more component(s) has/have become displaced during the transport of the boat to the testing station.

12. A method according to claim 10 wherein the method further comprises the steps of,
if it is identified that no component has become displaced during transport of the boat to the testing station, then, performing testing of the components on the boat;
if it is identified that one or more components have become displaced during transport of the boat to the testing station, then, returning the boat to a loading area without testing any of the components on the boat, and, either,
consecutively picking all components from the boat using respective component handling heads on a turret, so as to remove all components from the boat, and, rotating the turret in a first direction so that each of the picked components are consecutively brought to a station where step (a) is performed again, or
identifying the positions of the one or more components which have become displaced, and consecutively picking said one or more components only from the boat using respective component handling heads on the turret, so as to remove said one or more displaced components, and rotating the turret in a first direction so that the picked components are consecutively brought to a station where step (a) is performed again.

13. A method according to claim 1, wherein the method further comprises the steps of,
transporting the boat to a testing station where the components on the boat are tested;
after testing the components on the boat at the testing station:
transporting the boat from a testing station to an unloading station where components on the boat can be unloaded;
capturing a fourth image of the boat and said plurality of tested components at the unloading station;
using the fourth image to determine if a component has become displaced during the transport of the boat from the testing station to the unloading station.

14. A method according to claim 13, wherein:
the method further comprises the step of moving a component between a series of processing stations by rotating, in a first direction, a rotatable turret, which has a handling head which holds the component, before performing steps (b)-(e) at least, and wherein the method further comprises the step of passing a picked component through the series of processing stations for a second time after it has been picked,
the step of using the fourth image to determine if a component has become displaced during the transport of the boat to the unloading station comprises,
comparing the fourth image to the second image; and
identifying, based on the comparison of the second and fourth images, if a component has become displaced during the transport of the boat from the testing station to the unloading station.

15. An component handling assembly suitable for carrying out the method of claim 1, the assembly comprising:
(a) an alignment means operable to align an component into a predefined orientation;
(b) a turret comprising one or more component handling heads each of which can place an component on a boat which is located in a loading area;
(c) a first camera arranged for capturing a first image of an component after it has been placed on the boat;
(d) a processor configured such that it can use the first image to identify if the component in a predefined orientation on the boat, and can initiate a component handling head to pick the component if the component is not placed in the predefined orientation on the boat and initiate subsequent rotation of the turret so that the picked component is transported to the alignment means where it can be aligned again.
